(19) United States
(12) Patent Application Publication
(10) Pub. No.: US 2015/0144319 A1
(43) Pub. Date: May 28, 2015

(54) PART OF A CONTAINER FOR ELECTRONIC EQUIPMENT, HAVING THE FUNCTION OF A HEAT SINK, AND METHOD FOR MAKING IT

(71) Applicant: Gianfranco NATALI, Sorengo (CH)

(72) Inventor: Gianfranco NATALI, Sorengo (CH)

(21) Appl. No.: 14/550,102

(22) Filed: Nov. 21, 2014

(30) Foreign Application Priority Data
Nov. 25, 2013 (IT) VR2013A000255

(51) Int. Cl. H05K 7/20; B22D 19/00; B29C 45/14

(52) U.S. Cl. CPC H05K 7/20409; B29C 45/14631; B22D 19/0063; B29L 2031/712
USPC 165/185; 264/279; 164/98

(57) ABSTRACT

A part (1) of a container for electronic equipment, having the function of a heat sink, comprises a base (2) having mainly two-dimensional extension parallel with a first plane of extension, and a plurality of dissipation fins (3) fixed to the base (2) and also having mainly two-dimensional extension parallel with one or more second planes of extension which are transversal to the first plane of extension. The part (1) comprises a supporting body (4) and one or more metal inserts (5) irremovably connected to the supporting body (4), each metal insert (5) being constituted of a single piece made by extrusion and comprising a group of fins (3) and a connecting portion (7) connecting the fins (3) of the group to one another and at least partly irremovably embedded in the supporting body (4) by overmolding of the supporting body on the insert (5); the base (2) of the part (1) is constituted of both the supporting body (4) and each connecting portion (7) of the one or more inserts (5).

### CROSS-REFERENCE TO RELATED APPLICATIONS

The present application claims the benefit of Italian Patent Application VR2013A000255 filed on Nov. 25, 2013, which is incorporated herein by reference in its entirety.

### FIELD OF THE INVENTION

This invention relates to a part of a container for electronic equipment, having the function of a heat sink, and a method for making it.

In fact, this invention was originally intended for the production of containers for electronic equipment such as, in particular, filters and antennas for telecommunications. However, it may be applied to any other type of container also having the function of a heat sink and having similar features and issues.

### BACKGROUND OF THE INVENTION

In general, a container for electronic equipment which has the function of a heat sink of the type according to this invention consists of a sort of box comprising a containment element which is open at the top and a lid which can be removably fixed to the containment element so as to close the top of it. The “part” to which this invention relates may therefore be either the lid or the containment element (or any other part in the case of more complex structures) provided that it has the function of a heat sink. Said part which has the function of a heat sink generally comprises a base extending mainly two-dimensionally, parallel with a first plane of extension (the fact that it extends mainly two-dimensionally is more noticeable if it is a lid, whilst it is obviously much less noticeable if it is a containment element, which has a certain height in order to allow it to house the electronic equipment), and a plurality of dissipation fins fixed to the base, projecting relative to the base. The fins also extend mainly two-dimensionally, parallel with one or more second planes of extension which are transversal/perpendicular to the first plane of extension.

The known containers for electronic equipment for which this invention is intended are also usually made of aluminum or aluminum alloys.

Currently, heat sinks are usually made using two methods, depending on the structure of the heat sinks.

In fact, for the simpler heat sinks, where in the heat sink it is possible to identify a main line transversally to which the cross-section is substantially the same along the entire heat sink, the known technology involves production by extrusion.

However, that technology is not suitable for making parts of a container for electronic equipment which have the function of a heat sink and in which, inserted between the fins, there are also other elements projecting or recessed from/in the base, as in the case of the part illustrated in FIG. 1 (which shows a lid of a container for electronic equipment).

For the parts of a container for electronic equipment which have the function of a heat sink, the production method currently used is die-casting,

However, the main disadvantage of this production method is that, to allow processing and extraction from the mold, it requires much more material than is strictly necessary solely in terms of thermal dissipation, which is almost exclusively linked to the heat exchange surface area. In fact, in order to be able to extract the finished piece from the mold, in cross-section the lateral walls of the fins must have a significant taper from the base towards the tip.

### SUMMARY OF THE INVENTION

In this context, the technical purpose which forms the basis of this invention is to provide a part of a container for electronic equipment, having the function of a heat sink, and a method for making it which overcome the above-mentioned disadvantages.

In particular, the technical purpose of this invention is to provide a part of a container for electronic equipment which has the function of a heat sink and which, the composition of the material and the dispersion surface area being equal, uses less material than the prior art parts.

In other words, the technical purpose of this invention is to provide a part of a container for electronic equipment which has the function of a heat sink and which, the general structure and the heat exchange surface area being equal, weighs less than the prior art parts.

It is also the technical purpose of this invention to define a method for making a part of a container for electronic equipment which has the function of a heat sink and which allows the above-mentioned aims to be achieved.

The technical purpose specified and the aims indicated are substantially achieved by a part of a container for electronic equipment, having the function of a heat sink, and a method for making it as described in the appended claims.

Further features and the advantages of this invention are more apparent in the following detailed description of some non-limiting embodiments of a part of a container for electronic equipment which has the function of a heat sink and of a method for making it.

### BRIEF DESCRIPTION OF THE DRAWINGS

Reference will be made to the figures of the annexed drawings, wherein:

FIG. 1 is an axonometric view of a part of a container for electronic equipment which has the function of a heat sink, made in accordance with this invention;

FIG. 2 is an enlarged view of the detail II of FIG. 1;

FIG. 3 is a top view of the part of FIG. 1;

FIG. 4 is an enlarged view of the detail IV of FIG. 3;

FIG. 5 is an axonometric view of an extruded insert which is a component of the part of a container for electronic equipment of FIG. 1;

FIG. 6 is a top view of the insert of FIG. 5;

FIG. 7 is a front view of the insert of FIG. 5;

FIG. 8 is an enlarged view of the detail VIII of FIG. 7;

FIG. 9 is an enlarged view of the detail IX of FIG. 7;

FIG. 10 is a cross-section of a detail of the part of a container for electronic equipment of FIG. 1, at the insert of FIG. 5 and during the step of making it inside a mold; and

FIG. 11 is a front view of a different insert which can be used in accordance with this invention.

### DESCRIPTION OF EXAMPLE EMBODIMENTS

With reference to the accompanying drawings, the numeral 1 denotes in its entirety a part of a container for electronic equipment having the function of a heat sink, made according to this invention. Hereinafter, for simplicity it will often be referred to simply as the “part”.

Similarly to prior art parts, the part according to this invention comprises a base 2 extending mainly two-dimensionally, parallel with a first plane of extension, and a plurality of dissipation fins 3 fixed to the base 2, projecting from it cantilever-style, the dissipation fins 3 extending mainly two-dimensionally, parallel with one or more second planes of extension which are transversal (advantageously perpendicular) to the first plane of extension. According to a specific embodiment, the base 2 is substantially planar and the dissipation fins 3 extend transversally (in particular, perpendicularly) to the base 2, i.e. to its first plane of extension.

More precisely, if the container part 1 in question is the lid, the related base 2 extends almost exclusively two-dimensionally, whilst if it is the containment element of the container, it extends in the third dimension more significantly.

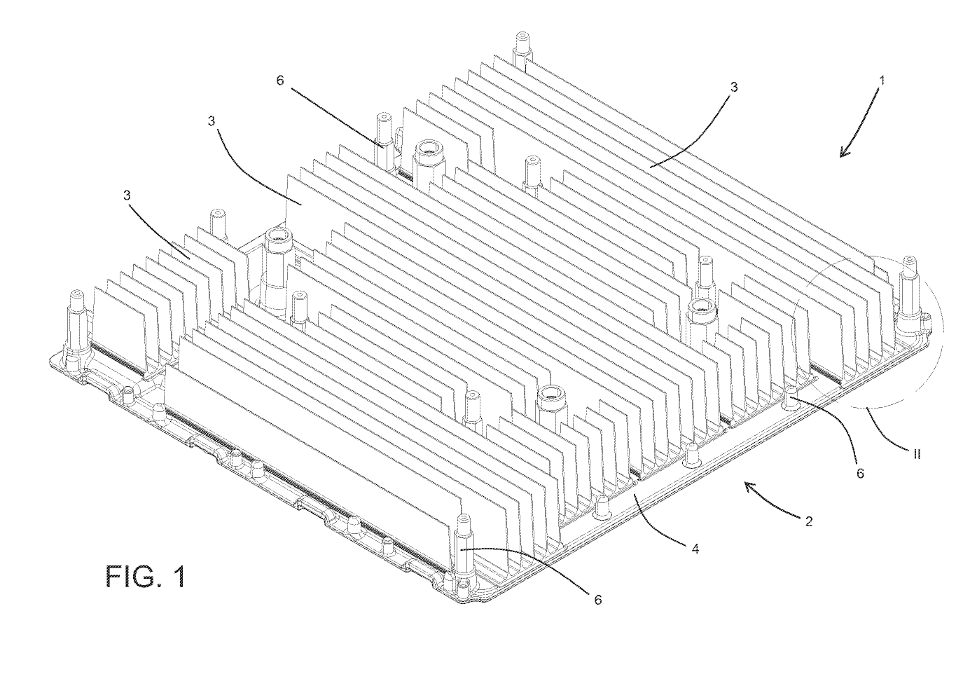

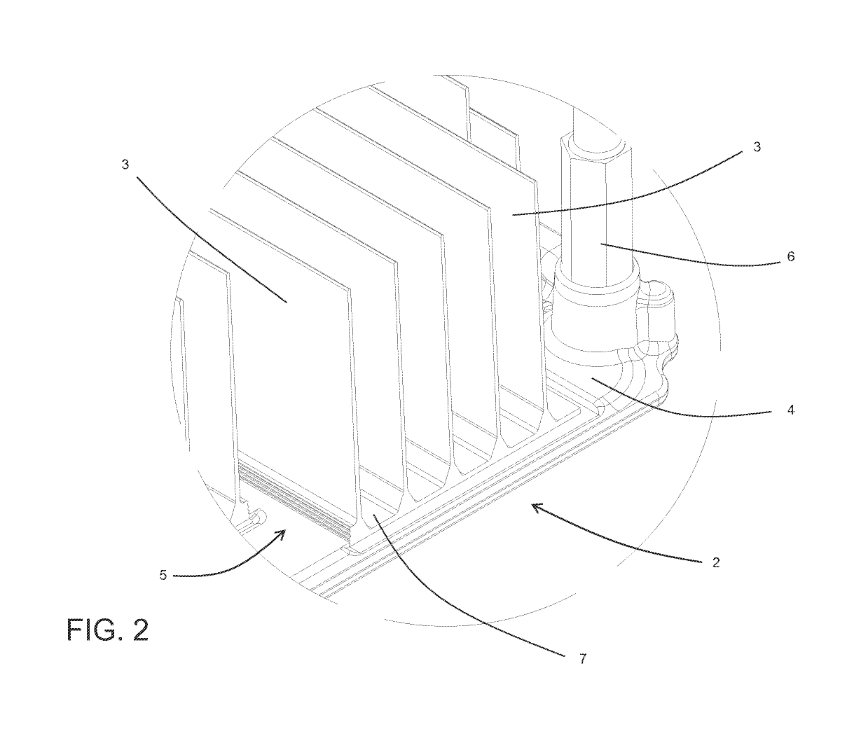

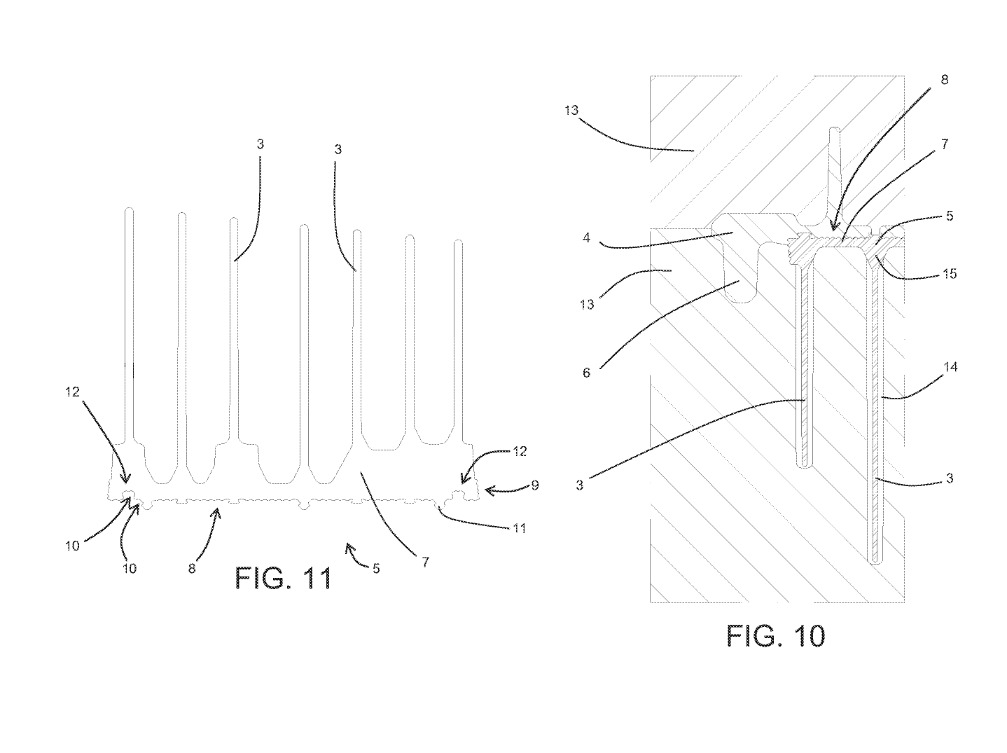

Regarding the innovative aspects of this invention, the part 1 first, although appearing to be a single element, in reality is constituted of at least two closely coupled pieces, In fact, in general it comprises a supporting body 4 and one or more metal inserts 5 irremovably connected to the supporting body 4. The supporting body 4 generally constitutes at least most of the base 2, whilst the fins 3 are advantageously at least mostly formed by the one or more inserts 5 (preferably the fins 3 are all formed by the inserts 5, but it is also possible that some fins 3 are advantageously made in one piece with the supporting body). Moreover, the supporting body 4 also forms, being in one piece with, other projecting elements 6, if present, of the part 1 (FIGS. 1 and 10).

As already indicated, according to this invention the inserts 5 are made of metal. They may be made of any metal suitable for the purpose (preferably aluminum or its alloys). The supporting body 4 may also be made of metal.

If so, both the supporting body 4 and the inserts 5 may be made either mainly of the same metal, if necessary differently alloyed, or of different metals in order to optimize performance during use, However, in some embodiments the supporting body 4 may even be made of a plastic material. If so, advantageously, suitable solutions may be adopted to allow, during use, the heat generated by the electronic equipment to reach the fins 3 so that it can be dissipated by them. By way of non-exhaustive examples, the plastic material may be made in such a way that it is a thermal conductor, or the inserts 5 may be positioned in such a way that they are directly facing the inside of the container, thereby directly receiving the heat, or there may be systems for transmitting the heat from the inside of the container, through the supporting body 4, to the metal inserts.

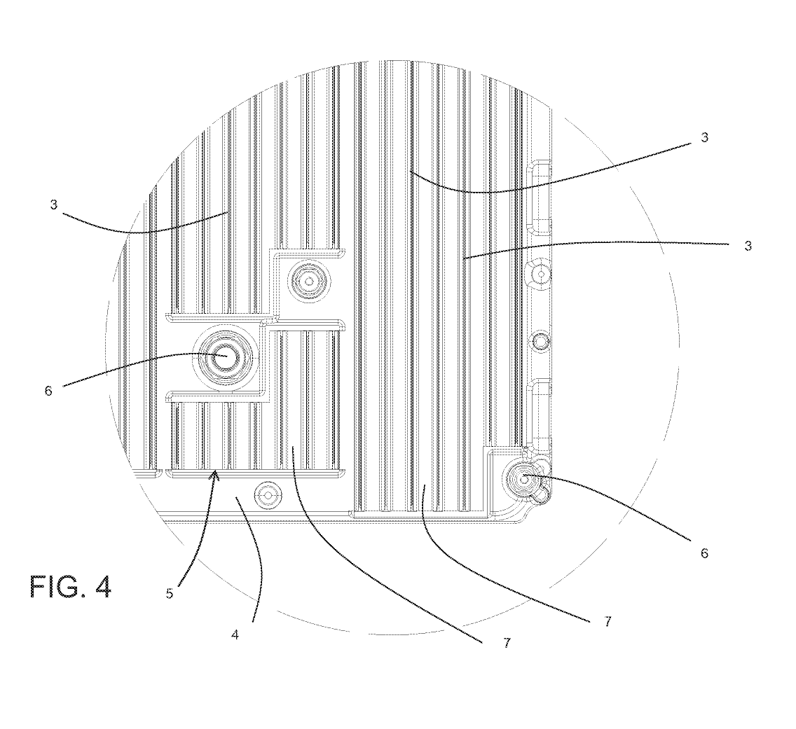

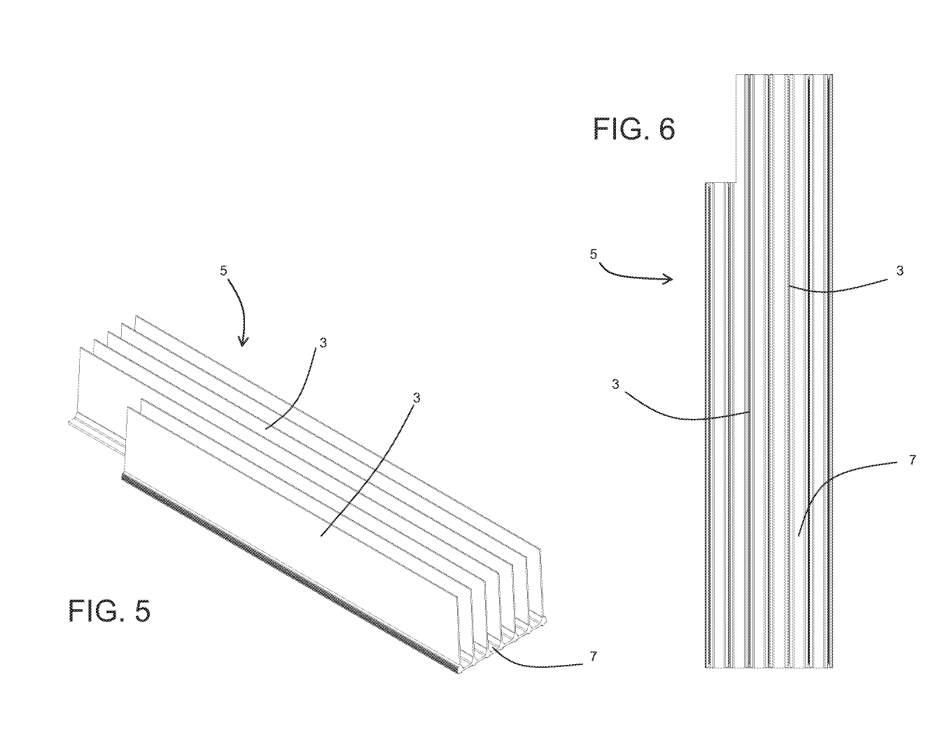

Each insert 5 is constituted of a single piece in which it is possible to identify a group of fins 3 and a connecting portion 7 which connects the fins 3 of the group to one another and which extends mainly parallel with the first plane of extension. As shown in FIG. 5, 7 or 11, each insert 5 has, to a first approximation, an overall shape similar to that of a conventional heat sink.

Moreover, advantageously, each insert 5 is made by extrusion. Therefore, each insert 5 is an extruded metal component. In any case, as illustrated by way of example in FIG. 11, the shape of each insert 5, as well as the shape of the related fins 3 and connecting portion 7, may vary according to requirements.

According to a second aspect of this invention, the connecting portion 7 of each insert 5 is also at least partly embedded in the supporting body 4 in an irremovable manner, by overmolding of the supporting body 4 on the one or more inserts 5. Thus, the supporting body 4 is an overmolded body that is overmolded over all the connecting portions 7 of the inserts 5.

In this way, the base 2 comprises both the supporting body 4 and each connecting portion 7 of the one or more inserts 5. Therefore, the connecting portions 7 are included or embedded in the base 2.

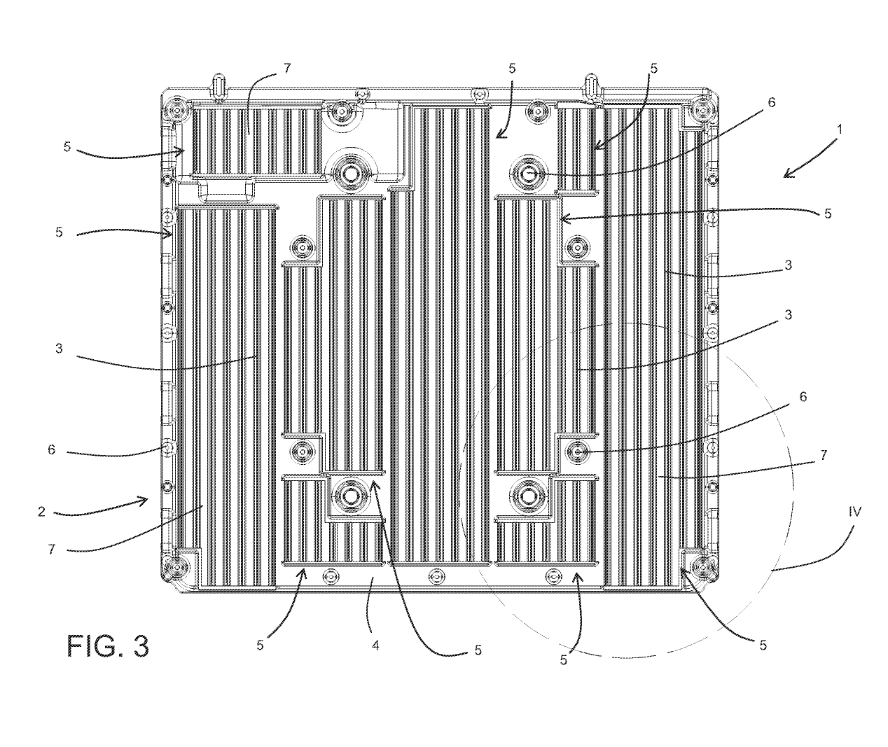

As shown in FIG. 3 (where each insert 5 is labelled with its own reference number), the part 1 illustrated in the accompanying drawings comprises a total of nine inserts 5, seven of which have seven fins 3 each, one having three fins and one having nine fins.

Even in the same insert 5, the fins 3 may have different lengths and/or different heights, and at the two ends they may have a face which is set at an angle to the line perpendicular to the first plane of extension.

Advantageously, the connecting portion 7 of each insert 5 has a coupling surface 8 at least partly embedded in the supporting body 4. As is clearly shown in FIGS. 7 and 11, in the embodiment illustrated, the coupling surface 8 advantageously comprises both the face of the connecting portion 7 opposite to that to which the fins 3 are fixed, and the two lateral faces 9 extending substantially parallel with the line of extension of the fins 3.

However, in other embodiments, the coupling surface 8 may also have other shapes according to requirements.

However, preferably, one or more undercut zones 10 are made in the coupling surface 8, to prevent uncoupling of the connecting portion 7 from the supporting body 4. The undercut zones 10, in particular, are made at projecting portions 11 and/or recessed portions 12 of the coupling surface 8 itself. Some examples of projecting portions 11 and recessed portions 12 can be seen in FIGS. 9 and 11.

To be more specific, the fins 3 project and extend from a first face of the connecting portion 7, whereas the undercut zones 10 (in particular, the projecting portions 11 and/or the recessed portions 12) are located on the bottom face of the connecting portion 7, i.e. on a second face of the connecting portion 7 that is opposite to the first face from which the fins 3 project and extend.

Moreover, advantageously, to guarantee improved adhesion between the insert 5 and the supporting body 4 and to achieve suitable heat transfer between the two, in cross-section relative to the line of extension of the fins 3, the coupling surface 8 has an undulating trend and the overmolding is performed in such a way that the gap present between the inserts 5 and the supporting body 4 is not greater than 10 μm. Said very small gap also prevents the passage of moisture and the transmission of electromagnetic waves, whilst the undulation of the coupling surface 8 increases the surface area for contact between the two materials, therefore guaranteeing improved heat exchange.

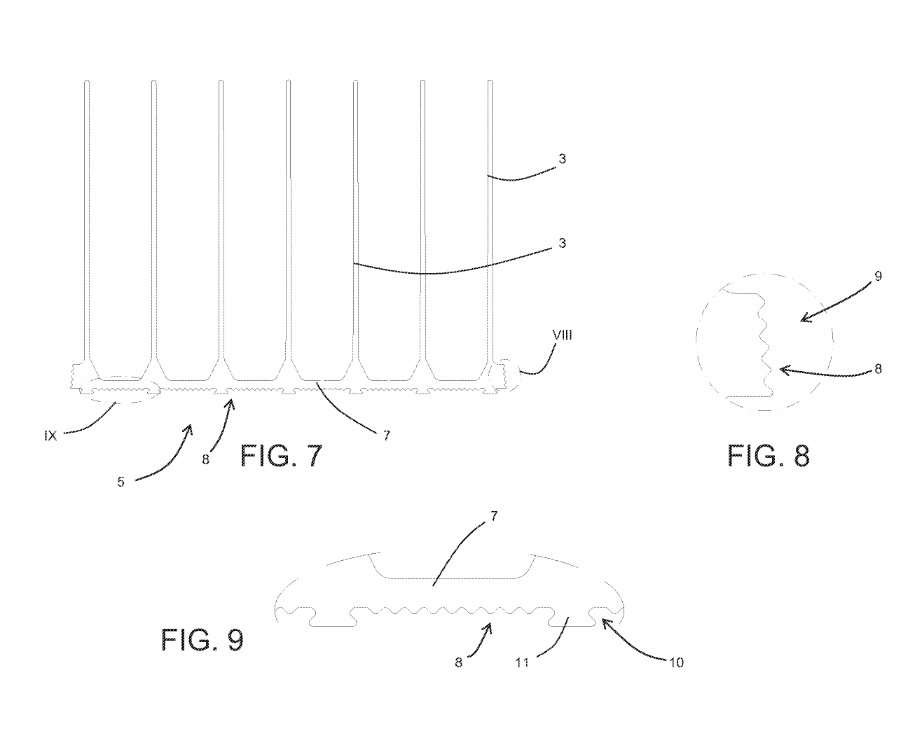

FIG. 8 shows how an undulating trend of the coupling surface 8 is present even at the lateral faces 9 of the connecting portion 7. The lateral faces 9 also converge slightly with one another towards the fins 3. Both the undulation and the convergence improve the coupling between the insert and the supporting body 4, but, as is explained in more detail below, at least the undulation has an advantageous function also during production of the part 1.

In particular, the base 2 has a thickness, along a line perpendicular to its first plane of extension. The connecting portions 7 are included only in a section of the thickness of the base 2 and then the inserts 5 project only from one face of the base 2, i.e. they project only from the face from which the fins 3 project as well. In other words, each connecting portion 7 takes only a first section of the thickness of the base 2: the thickness of the base 2 has a second section which is not penetrated by the inserts 5. This is useful for maximizing the surface area for contact of the coupling surface 8 with the supporting body 4, to the benefit of the heat exchange between the base 2 and the fins 3, and of the strength of the coupling between the inserts 5 and the supporting body 4.

It should be noticed that this invention also relates to the individual insert 5 described above and constituted of a single piece which comprises the connecting portion 7 and the group of dissipation fins 3, and where the connecting portion 7 comprises a coupling surface 8 in which one or more undercut zones 10 are made, to prevent uncoupling of the connecting portion 7 from the supporting body 4 and/or where the coupling surface 8 has at least some undulating portions.

As already indicated, this invention also relates to a method for making the part 1 of the container described above.

Said method comprises making the part 1 in two or more steps, and in particular comprises at least the operating steps of:
producing, by extrusion, one or more metal inserts 5 in each of which it is possible to identify a group of cantilever fins 3 and a connecting portion 7 which connects the fins 3 of the group to one another; and
at least partly irremovably embedding the connecting portions 7 of the one or more metal inserts 5 in the supporting body 4 by overmolding the supporting body 4 on the one or more inserts 5, for rigidly constraining the one or more metal inserts 5 to one another and to the supporting body 4.

Therefore, at the end of the embedding step, the supporting body 4 and the one or more connecting portions 7 together form the base 2 of the part 1.

Advantageously, the embedding step comprises die-casting of the supporting body 4 in a mold 13 in which the one or more inserts 5 have been inserted beforehand.

In the preferred embodiment of the method according to this invention, the step of embedding the one or more inserts 5 in the supporting body 4 therefore comprises the step of inserting each insert 5 in a mold 13, the step of creating a seal for the liquid material between the connecting portion 7 and the mold 13, and the step of injecting the pressurized liquid material (advantageously metal or plastic, as explained above) into the mold 13, advantageously all in such a way that the mold 13 is emptied of any air in it before and/or during actual injection of the liquid material.

Advantageously, to guarantee correct positioning of the various inserts 5, the mold 13 may comprise a housing 14 at each fin 3. As shown in FIG. 10, each housing 14 may be larger than the related fin 3, which therefore does not make contact with the walls of the housing 14 but rests in a sealed fashion at its base portion 15 close to the connecting portion 7.

The step of injecting the liquid material into the mold 13 is advantageously carried out at a suitable pressure which is maintained until the mold is completely full and until initial solidification of the liquid material has taken place, so as to achieve optimum adhesion of the supporting body 4 to the inserts 5.

Finally, the step of creating a seal between the mold 13 and each insert 5 is advantageously performed at the undulating lateral faces 9 of each insert 5.

This invention brings important advantages.

First, thanks to this invention it was possible to make a part of a container for electronic equipment having the function of a heat sink which, the composition of the material and the dispersion surface area being equal, requires much less material than the completely die-cast prior art parts. By way of example, when making the part of a container illustrated in the accompanying drawings it was, in fact, possible to reduce the amount of aluminum used by 42% compared with a previous similar part which was completely die-cast.

Second, tests carried out allowed it to be ascertained that in the part of a container according to this invention even heat conduction and dissipation are improved compared with the previous, completely die-cast part.

Finally, thanks to the fact that each insert comprises a certain number of fins, the positioning of the inserts in the mold is fast and easy.

In conclusion, it should be noticed that this invention is generally relatively easy to make and that even the cost linked to implementing the invention is not very high.

The invention described above may be modified and adapted in several ways without thereby departing from the scope of the inventive concept.

Moreover, all details of the invention may be substituted with other technically equivalent elements and the materials used, as well as the shapes and dimensions of the various components, may vary according to requirements.

1. A container part (1), comprising:
a base (2) having mainly two-dimensional extension parallel with a first plane of extension, the base (2) comprising a supporting body (4); and
one or more extruded metal inserts (5) irremovably connected to the supporting body (4), each of said one or more extruded metal inserts (5) comprising a respective group of dissipation fins (3);
wherein each of said one or more extruded metal inserts (5) is produced by extrusion and is constituted of a single piece comprising the respective group of dissipation fins (3) and a connecting portion (7) which connects the dissipation fins (3) of the group to one another;
wherein, in the container part (1), each connecting portion (7) is at least partly irremovably embedded in the supporting body (4), so that the base (2) includes each connecting portion (7) of said one or more extruded metal inserts (5) and the dissipation fins (3) are fixed to the base (2), the dissipation fins (3) having mainly two-dimensional extension parallel with one or more second planes of extension which are transversal to the first plane of extension of the base (2),
the container part (1) having a function of a heat sink for a container intended to contain electronic equipment.

2. The container part (1) according to claim 1, wherein the connecting portion (7) of each of said one or more extruded metal inserts (5) comprises a coupling surface (8) which is at least partly embedded in the supporting body (4) and in which one or more undercut zones (10) are made to prevent uncoupling of the connecting portion (7) from the supporting body (4).

3. The container part (1) according to claim 2, wherein the undercut zones (10) are made at projecting portions (11) and/or recessed portions (12) of the coupling surface (8).

4. The container part (1) according to claim 2, wherein the coupling surface (8) has an undulating trend.

5. The container part (1) according to claim 2, wherein the dissipation fins (3) extend from a first face of the connecting portion (7) and said one or more undercut zones (10) are located on a second face of the connecting portion (7), the second face being opposite to the first face.

6. The container part (1) according to claim 1, wherein the base (2) has a thickness and each connecting portion (7) takes only a first section of the thickness of the base (2), the thickness of the base (2) having a second section which is not penetrated by said one or more extruded metal inserts (5).

7. The container part (1) according to claim 1, wherein the supporting body (4) is an overmolded body that is overmolded over each connecting portion (7) of the one or more metal inserts (5).

8. The container part (1) according to claim 1, the container part (1) being a lid for a container.

9. An extruded metal component (5) for a container part (1) having a function of a heat sink in a container intended to contain electronic equipment,
the extruded metal component (5) being constituted of a single piece which is produced by extrusion and comprises a connecting portion (7) having mainly two-dimensional extension parallel with a first plane of extension and a group of dissipation fins (3) fixed to the connecting portion (7), the dissipation fins (3) having mainly two-dimensional extension parallel with one or more second planes of extension which are transversal to the first plane of extension, the connecting portion (7) being intended to be at least partly irremovably embedded in a supporting body (4) of said container part (1),
the connecting portion (7) comprising a coupling surface (8) in which one or more undercut zones (10) are made to prevent uncoupling of the connecting portion (7) from the supporting body (4) and/or in which one or more undulating portions are made.

10. A method for making a part (1) of a container intended to contain electronic equipment, comprising the operating steps of:
producing, by extrusion, one or more metal inserts (5) in each of which it is possible to identify a group of dissipation fins (3) and a connecting portion (7) which connects the dissipation fins (3) of the group to one another;
at least partly irremovably embedding the connecting portion (7) of the one or more metal inserts (5) in a supporting body (4) by overmolding, for rigidly constraining the one or more metal inserts (5) relative to one another and to the supporting body (4), to obtain a container part (1) comprising a base (2) having mainly two-dimensional extension parallel with a first plane of extension, the base (2) comprising the supporting body (4) and the connecting portion (7) of the one or more metal inserts (5), the container part (1) further comprising said dissipation fins (3) which are fixed to the base (2) and have mainly two-dimensional extension parallel with one or more second planes of extension which are transversal to the first plane of extension of the base (2).

11. The method according to claim 10, wherein the embedding step comprises the sub-steps of:
inserting each metal insert (5) in a mold (13) comprising a housing (14) for the dissipation fins (3);
creating a seal at least between the connecting portion (7) of each metal insert (5) and the mold (13);
injecting a pressurized liquid material into the mold (13) to make the supporting body (4).

12. The method according to claim 11, wherein the liquid material is a metal material or a plastic material.

13. A container part (1) obtained using a method according to claim 10, the container part (1) having a function of a heat sink for a container intended to contain electronic equipment.

14. A container comprising a container part (1) according to claim 1, the container being intended to contain electronic equipment.

15. A container comprising a container part (1) according to claim 13, the container being intended to contain electronic equipment.
